(19) United States
(12) Patent Application Publication
(10) Pub. No.: US 2011/0278739 A1
(43) Pub. Date: Nov. 17, 2011

(54) Semiconductor Package

(76) Inventors: Yi-Shao Lai, Kaohsiung (TW); Tsung-Yueh Tsai, Kaohsiung (TW); Ming-Kun Chen, Kaohsiung (TW); Hsiao-Chuan Chang, Kaohsiung (TW); Ming-Hsiang Cheng, Kaohsiung (TW)

(21) Appl. No.: 12/777,442

(22) Filed: May 11, 2010

(51) Int. Cl. H01L 23/52

(52) U.S. Cl. 257/777; 257/E23.141

(57) ABSTRACT

The present invention relates to a semiconductor package. The semiconductor package includes a substrate, a first chip and an interposer. The first chip is mechanically and electrically connected to the substrate. Some signal pads of the interposer are capacitively coupled to some signal pads of the first chip, so as to provide proximity communication between the first chip and the interposer. Whereby, the capacitively coupled signal pads can be made in fine pitch, and therefore the size of the semiconductor package is reduced and the density of the signal pads is increased.

### BACKGROUND OF THE INVENTION

1. Field of the Invention

The present invention relates to a semiconductor package, and more particularly to a semiconductor package having capacitively coupled signal pads.

2. Description of the Related Art

FIG. 1 shows a cross-sectional view of a conventional semiconductor package. The conventional semiconductor package 1 comprises a first substrate 11, a first chip 12, an underfill 13, a dielectric layer 14, a second substrate 15, a plurality of wires 16, a molding compound 17 and a plurality of solder balls 18. The first substrate 11 has a first surface 111 and a second surface 112. The first chip 12 is disposed on the first substrate 11, and comprises a plurality of first bumps 121. The underfill 13 encapsulates the first bumps 121 of the first chip 12. The dielectric layer 14 is disposed on the first chip 12. The second substrate 15 is disposed on the dielectric layer 14, and comprises a first surface 151, a second surface 152 and a plurality of input/output pads 153. The first surface 151 contacts the dielectric layer 14. The input/output pads 153 are disposed on the second surface 152. The wires 16 electrically connect the second substrate 15 and the first substrate 11. The molding compound 17 encapsulates the first surface 111 of the first substrate 11, the first chip 12, the dielectric layer 14, the first surface 151 of the second substrate 15 and the wires 16, and exposes the input/output pads 153 of the second substrate 15. The solder balls 18 are disposed on the second surface 112 of the first substrate 11.

The conventional semiconductor package 1 has the following disadvantages. A dielectric layer 14 has to be disposed between the first chip 12 and the second substrate 15, so the thermal stability of fine pitch is decreased, the thickness of the semiconductor package 1 is increased and the manufacturing cost is increased.

Therefore, it is necessary to provide a semiconductor package to solve the above problems.

### SUMMARY OF THE INVENTION

The present invention is directed to a semiconductor package. The semiconductor package comprises a substrate, a first chip and an interposer. The substrate has a receiving surface. The first chip is mechanically and electrically connected to the substrate. The first chip comprises a first major surface, a first back surface, a plurality of first signal pads, a plurality of second signal pads, at least one first power pad, at least one second power pad and at least one first through-chip via. The first back surface faces the receiving surface of the substrate. The first signal pads are disposed adjacent to the first major surface. The second signal pads are disposed adjacent to the first back surface, and the first signal pads are electrically connected to the substrate via the second signal pads. The first power pad is disposed adjacent to the first major surface. The second power pad is disposed adjacent to the first back surface. The first through-chip via electrically connects the first power pad and the second power pad.

The interposer is mechanically and electrically connected to the first chip. The interposer comprises a first surface, a second surface, a plurality of third signal pads, a redistribution layer, at least one first through silicon via, at least one third power pad and at least one second through silicon via. The first surface faces the first major surface of the first chip. The third signal pads are disposed adjacent to the first surface and capacitively coupled to the first signal pads of the first chip, so as to provide proximity communication between the first chip and the interposer. The redistribution layer is disposed adjacent to the second surface, and has a plurality of fourth signal pads and at least one fourth power pad. The first through silicon via electrically connects the third signal pads and the fourth signal pads. The third power pad is disposed adjacent to the first surface. The second through silicon via electrically connects the third power pad and the fourth power pad.

The present invention is further directed to a semiconductor package. The semiconductor package comprises a substrate, a third chip and a fourth chip. The substrate has a receiving surface. The third chip is electrically connected to the substrate. The third chip comprises a third major surface, a third back surface, a plurality of sixth signal pads, a plurality of seventh signal pads, at least one second through-chip via, at least one sixth power pad, at least one seventh power pad and at least one third through-chip via. The third major surface faces the receiving surface of the substrate. The is sixth signal pads are disposed adjacent to the third major surface. The seventh signal pads are disposed adjacent to the third back surface. The second through-chip via electrically connects the sixth signal pads and the seventh signal pads. The sixth power pad is disposed adjacent to the third major surface. The seventh power pad is disposed adjacent to the third back surface. The third through-chip via electrically connects the sixth power pad and the seventh power pad.

The fourth chip is electrically connected to the third chip. The fourth chip comprises a fourth major surface, a plurality of eighth signal pads and at least one eighth power pad. The fourth major surface faces the third back surface of the third chip. The eighth signal pads are disposed adjacent to the fourth major surface and capacitively coupled to the seventh signal pads of the third chip, so as to provide proximity communication between the third chip and the fourth chip. The eighth power pad is disposed adjacent to the fourth major surface and electrically connected to the seventh power pad of the third chip.

Whereby, the capacitively coupled signal pads can be made in fine pitch, and therefore the size of the semiconductor package is reduced and the density of the signal pads is increased.

### BRIEF DESCRIPTION OF THE DRAWINGS

FIG. 1 is a cross-sectional view of a conventional semiconductor package;

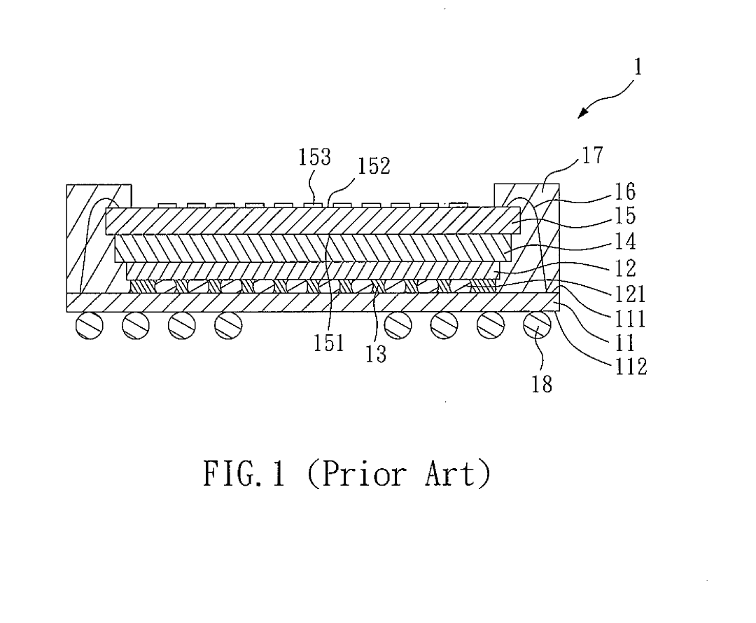

FIG. 2 is a cross-sectional view of a semiconductor package according to a first embodiment of the present invention;

FIG. 3 is a cross-sectional view of a semiconductor package according to a second embodiment of the present invention;

FIG. 4 is a cross-sectional view of a semiconductor package according to a third embodiment of the present invention;

FIG. 5 is a cross-sectional view of a semiconductor package according to a fourth embodiment of the present invention; and

FIG. 6 is a cross-sectional view of a semiconductor package according to a fifth embodiment of the present invention.

### DETAILED DESCRIPTION OF THE INVENTION

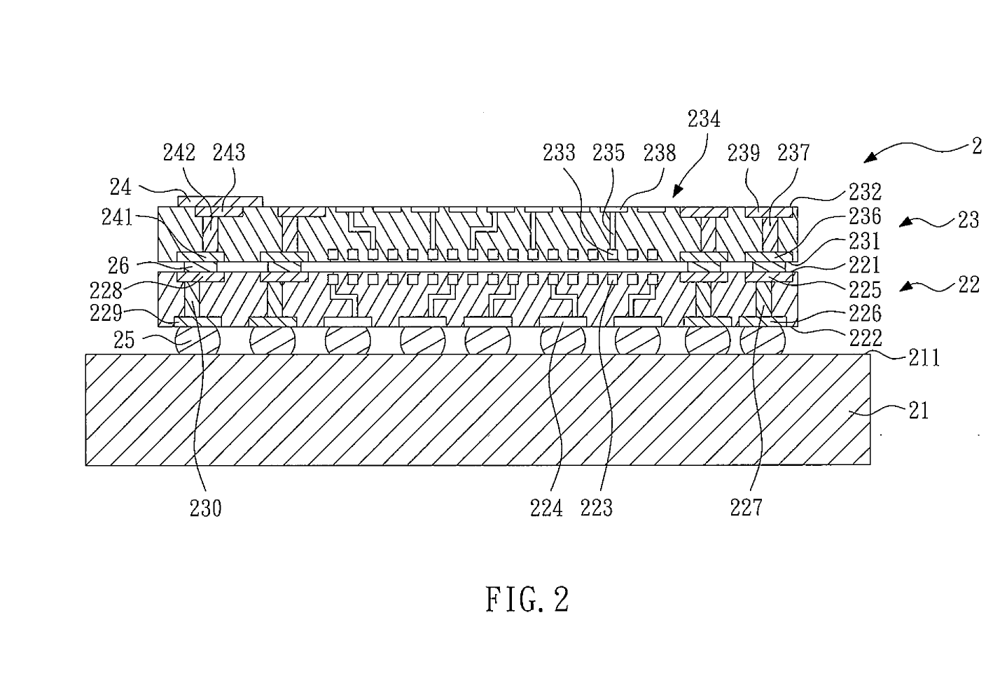

FIG. 2 shows a cross-sectional view of a semiconductor package according to a first embodiment of the present invention. The semiconductor package 2 comprises a substrate 21, a first chip 22 and an interposer 23. In the embodiment, the semiconductor package 2 further comprises at least one first passive device 24, at least one first conductive element 25 and at least one second conductive element 26.

The substrate 21 has a receiving surface 211. The first chip 22 is mechanically and electrically connected to the substrate 21 by the first conductive element 25. The first chip 22 has an active circuitry (not shown) embedded therein. The first chip 22 comprises a first major surface 221, a first back surface 222, a plurality of first signal pads 223, a plurality of second signal pads 224, at least one first power pad 225, at least one second power pad 226, at least one first through-chip via 227, at least one first ground pad 228, at least one second ground pad 229 and at least one fourth through-chip via 230. The first back surface 222 faces the receiving surface 211 of the substrate 21. The first signal pads 223 are disposed adjacent to the first major surface 221. The second signal pads 224 are disposed adjacent to the first back surface 222, and the first signal pads 223 are electrically connected to the substrate 21 via the second signal pads 224, respectively. The first power pad 225 and the first ground pad 228 are disposed adjacent to the first major surface 221. The second power pad 226 and the second ground pad 229 are disposed adjacent to the first back surface 222. The first through-chip via 227 electrically connects the first power pad 225 and the second power pad 226. The first power pad 225 and the second power pad 226 are used for transmitting electrical power. The fourth through-chip via 230 electrically connects the first ground pad 228 and the second ground pad 229.

The interposer 23 is mechanically and electrically connected to the first chip 22. The interposer 23 may be formed from an inactive silicon wafer without an active circuitry embedded therein. The interposer 23 comprises a first surface 231, a second surface 232, a plurality of third signal pads 233, a redistribution layer 234, at least one first through silicon via 235, at least one third power pad 236, at least one second through silicon via 237, at least one third ground pad 241 and at least one fifth through silicon via 242. The first surface 231 faces the first major surface 221 of the first chip 22. The third signal pads 233 are disposed adjacent to the first surface 231 and capacitively coupled to the first signal pads 223 of the first chip 22, so as to provide proximity communication between the first chip 22 and the interposer 23. The redistribution layer 234 is disposed adjacent to the second surface 232, and has a plurality of fourth signal pads 238, at least one fourth power pad 239 and at least one fourth ground pad 243. The first through silicon via 235 electrically connects the third signal pads 233 and the fourth signal pads 238. The third power pad 236 and the third ground pad 241 are disposed adjacent to the first surface 231. The second through silicon via 237 electrically connects the third power pad 236 and the fourth power pad 239. The third power pad 236 and the fourth power pad 239 are used for transmitting electrical power. The fifth through silicon via 242 electrically connects the third ground pad 241 and the fourth ground pad 243.

It should be noted that the first chip 22 and the interposer 23 communicate with each other through proximity communication between the first signal pads 223 and the third signal pads 233, instead of direct electrical connections; however, electrical power or ground is transmitted between the first chip 22 and the interposer 23 through direct electrical connections (e.g., the second conductive element 26 such as solder bumps or copper pillars).

In order to achieve the function of proximity communication, part of the first chip 22 and the interposer 23 are placed face-to-face in a manner that aligns the transmitter circuit with the receiver circuit in extremely close proximity, for example, with only microns of separation between them. The signals between the transmitter circuit and the receiver circuit may be transmitted by inductive or capacitive coupling with low overall communication cost.

Take transmission by capacitive coupling for example. The first signal pads 223 of the first chip 22 and the third signal pads 233 of the interposer 23 are aligned with each other. Since the first signal pads 223 and the third signal pads 233 are not in physical contact with each other, there are capacitances between the first signal pads 223 of the first chip 22 and the third signal pads 233 of the interposer 23. It is this capacitive coupling that provides signal paths between the first chip 22 and the interposer 23. Changes in the electrical potential of the first signal pads 223 of the first chip 22 cause corresponding changes in the electrical potential of the corresponding third signal pads 233 of the interposer 23. Suitable drivers of the transmitter circuit and sensing circuits of the receiver circuit in the first chip 22 and the interposer 23 make communication through this small capacitance possible.

In the embodiment, the first passive device 24 is disposed adjacent to the interposer 23. The first conductive element 25 is used for connecting the first chip 22 and the substrate 21, and preferably, the first conductive element 25 is a solder ball. The second conductive element 26 is used for connecting the first chip 22 and the interposer 23, and preferably, the second conductive element 26 is a bump or a metal pillar.

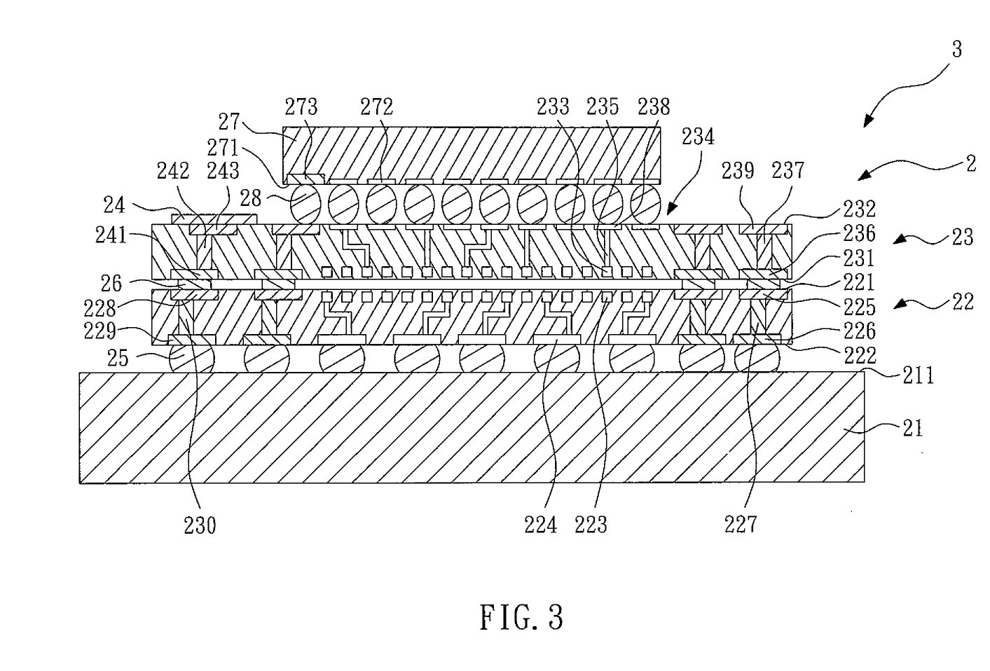

FIG. 3 shows a cross-sectional view of a semiconductor package according to a second embodiment of the present invention. The semiconductor package 3 according to the second embodiment is substantially the same as the semiconductor package 2 (FIG. 2) according to the first embodiment, and the same elements are designated by the same reference numbers. The difference between the semiconductor package 3 according to the second embodiment and the semiconductor package 2 (FIG. 2) according to the first embodiment is that the semiconductor package 3 further comprises a second chip 27 disposed on the second surface 232 of the interposer 23 and electrically connected to the interposer 23. In the embodiment, the second chip 27 is electrically connected to the interposer 23 via flip-chip bonding. The second chip 27 comprises a second major surface 271, a plurality of fifth signal pads 272, at least one fifth power pad 273 and at least one fifth ground pad (not shown). The fifth signal pads 272 are disposed adjacent to the second major surface 271 and electrically connected to the fourth signal pads 238 of the interposer 23. The fifth power pad 273 and the fifth ground pad are disposed adjacent to the second major surface 271 and electrically connected to the fourth power pad 239 and the fourth ground pad 243 of the interposer 23, respectively. The fifth power pad 273 is used for transmitting electrical power. The semiconductor package 3 further comprises at least one third conductive element 28 for connecting the interposer 23 and the second chip 27, and preferably, the third conductive element 28 is a bump.

In this embodiment, the interposer 23 is used for distributing finer pitch connections of the second chip 27 stacked above to the third signal pads 233 which are capable of capacitively coupling to the first signal pads 223 of the first chip 22.

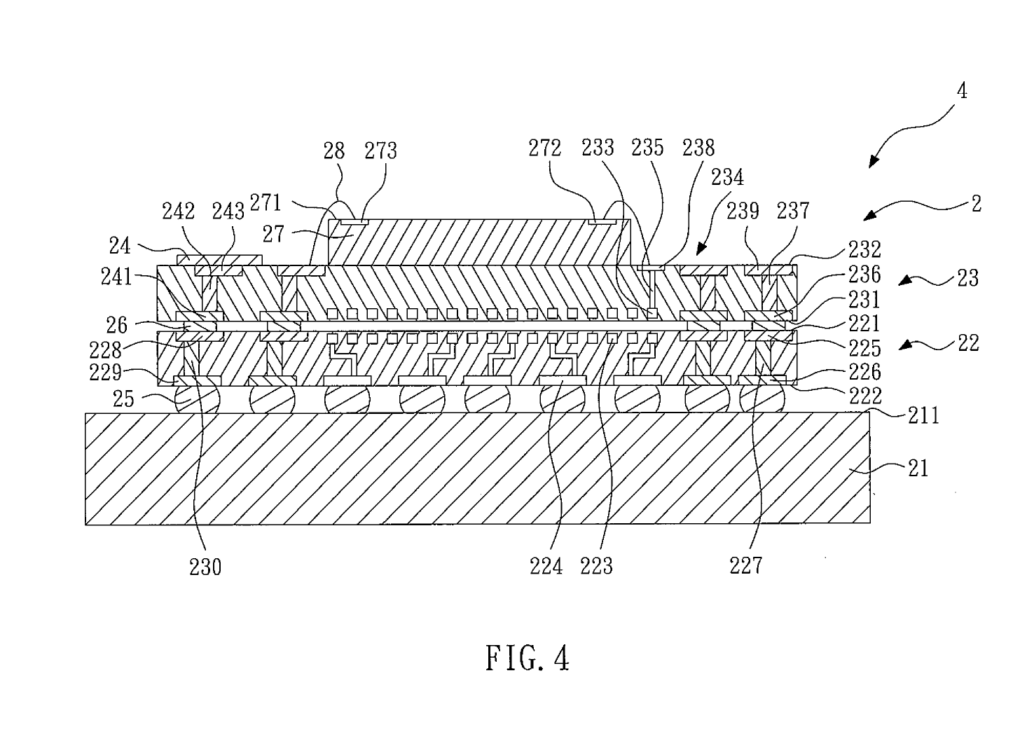

FIG. 4 shows a cross-sectional view of a semiconductor package according to a third embodiment of the present invention. The semiconductor package 4 according to the third embodiment is substantially the same as the semiconductor package 3 (FIG. 3) according to the second embodiment, and the same elements are designated by the same reference numbers. The difference between the semiconductor package 4 according to the third embodiment and the semiconductor package 3 (FIG. 3) according to the second embodiment is that the second chip 27 is electrically connected to the interposer 23 via wire-bonding. The third conductive element 28 is a wire.

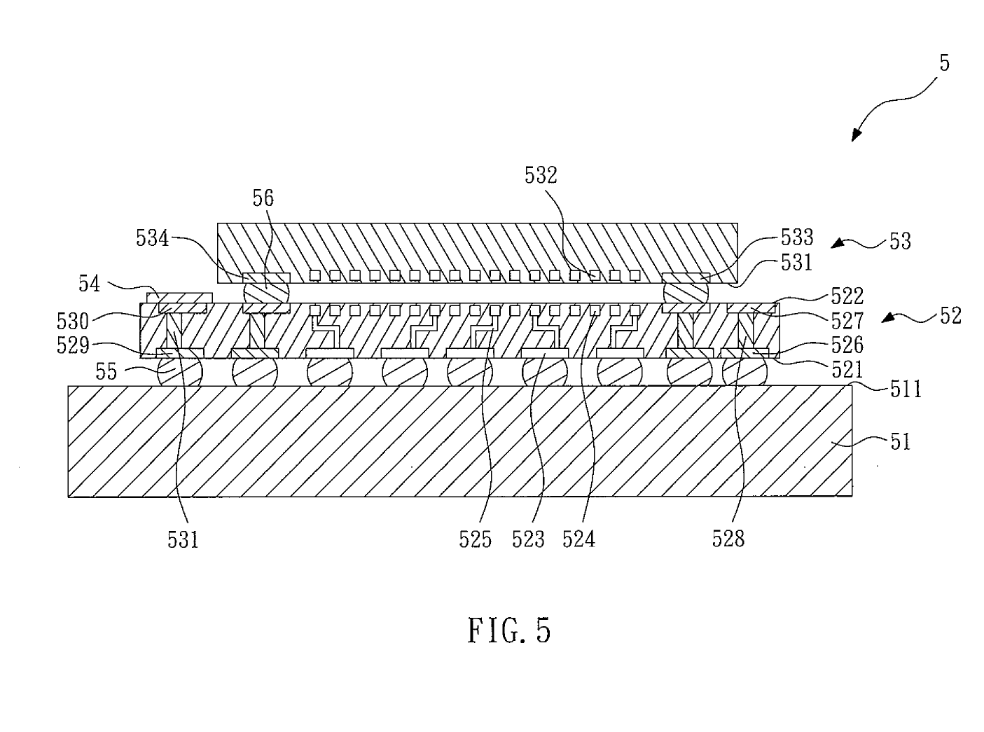

FIG. 5 shows a cross-sectional view of a semiconductor package according to a fourth embodiment of the present invention. The semiconductor package 5 comprises a substrate 51, a third chip 52 and a fourth chip 53. In the embodiment, the semiconductor package 5 further comprises at least one second passive device 54, at least one fourth conductive element 55 and at least one fifth conductive element 56.

The substrate 51 has a receiving surface 511. The third chip 52 is electrically connected to the substrate 51. The third chip 52 comprises a third major surface 521, a third back surface 522, a plurality of sixth signal pads 523, a plurality of seventh signal pads 524, at least one second through-chip via 525, at least one sixth power pad 526, at least one seventh power pad 527, at least one third through-chip via 528, at least one sixth ground pad 529, at least one seventh ground pad 530 and at least one fifth through-chip via 531. The third major surface 521 faces the receiving surface 511 of the substrate 51. The sixth signal pads 523 are disposed adjacent to the third major surface 521. The seventh signal pads 524 are disposed adjacent to the third back surface 522. The second through-chip via 525 electrically connects the sixth signal pads 523 and the seventh signal pads 524. The sixth power pad 526 and the sixth ground pad 529 are disposed adjacent to the third major surface 521. The seventh power pad 527 and the seventh ground pad 530 are disposed adjacent to the third back surface 522. The third through-chip via 528 electrically connects the sixth power pad 526 and the seventh power pad 527. The fifth through-chip via 531 electrically connects the sixth ground pad 529 and the seventh ground pad 530.

The fourth chip 53 is electrically connected to the third chip 52. The fourth chip 53 comprises a fourth major surface 531, a plurality of eighth signal pads 532, at least one eighth power pad 533, at least one eighth ground pad 534. The fourth major surface 531 faces the third back surface 522 of the third chip 52. The eighth signal pads 532 are disposed adjacent to the fourth major surface 531 and capacitively coupled to the seventh signal pads 524 of the third chip 52, so as to provide proximity communication between the third chip 52 and the fourth chip 53. The eighth power pad 533 and the eighth ground pad 534 are disposed adjacent to the fourth major surface 531 and electrically connected to the seventh power pad 527 and the seventh ground pad 530 of the third chip 52, respectively.

In the embodiment, the second passive device 54 is disposed adjacent to the third chip 52. The fourth conductive element 55 is used for connecting the third chip 52 and the substrate 51, and preferably, the fourth conductive element 55 is a solder ball. The fifth conductive element 56 is used for connecting the third chip 52 and the fourth chip 53, and preferably, the fifth conductive element 56 is a bump or a metal pillar.

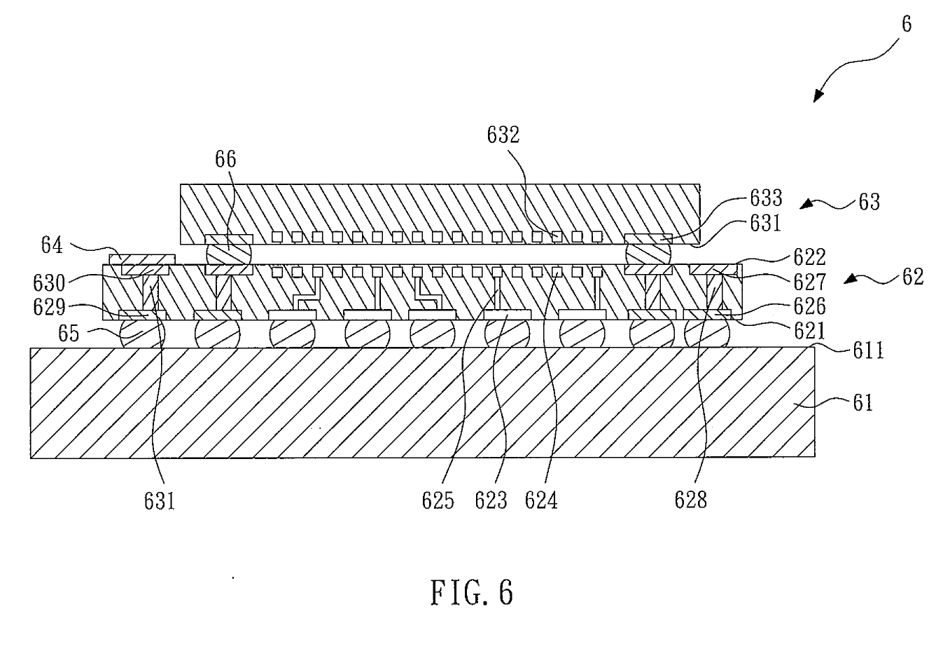

FIG. 6 shows a cross-sectional view of a semiconductor package according to a fifth embodiment of the present invention. The semiconductor package 6 comprises a substrate 61, an interposer 62 and a fifth chip 63. In the embodiment, the semiconductor package 6 further comprises at least one third passive device 64, at least one sixth conductive element 65 and at least one seventh conductive element 66.

The substrate 61 has a receiving surface 611. The interposer 62 is electrically connected to the substrate 61. The interposer 62 comprises a first surface 621, a second surface 622, a plurality of eighth signal pads 623, a plurality of ninth signal pads 624, at least one third through silicon via 625, at least one ninth power pad 626, at least one tenth power pad 627, at least one fourth through silicon via 628, at least one ninth ground pad 629, at least one tenth ground pad 630 and at least one sixth through silicon via 631. The first surface 621 faces the receiving surface 611 of the substrate 61. The eighth signal pads 623 are disposed adjacent to the first surface 621. The ninth signal pads 624 are disposed adjacent to the second surface 622. The third through silicon via 625 electrically connects the eighth signal pads 623 and the ninth signal pads 624. The ninth power pad 626 and the ninth ground pad 629 are disposed adjacent to the first surface 621. The tenth power pad 627 and the tenth ground pad 630 are disposed adjacent to the second surface 622. The fourth through silicon via 628 electrically connects the ninth power pad 626 and the tenth power pad 627. The sixth through silicon via 631 electrically connects the ninth ground pad 629 and the tenth ground pad 630.

The fifth chip 63 is electrically connected to the interposer 62. The fifth chip 63 comprises a fifth major surface 631, a plurality of tenth signal pads 632, at least one eleventh power pad 633 and at least one eleventh ground pad 634. The fifth major surface 631 faces the second surface 622 of the interposer 62. The tenth signal pads 632 are disposed adjacent to the fifth major surface 631 and capacitively coupled to the ninth signal pads 624 of the interposer 62, so as to provide proximity communication between the interposer 62 and the fifth chip 63. The eleventh power pad 633 and the eleventh ground pad 634 are disposed adjacent to the fifth major surface 631 and electrically connected to the tenth power pad 627 and the tenth ground pad 630 of the interposer 62, respectively. In the embodiment, the third passive device 64 is disposed adjacent to the interposer 62. The sixth conductive element 65 is used for connecting the interposer 62 and the substrate 61, and preferably, the sixth conductive element 65 is a solder ball. The seventh conductive element 66 is used for connecting the interposer 62 and the fifth chip 63, and preferably, the seventh conductive element 66 is a bump or a metal pillar.

Whereby, the capacitively coupled signal pads 223, 235, 524, 532, 624, 632 can be made in fine pitch, and therefore the size of the semiconductor package 2, 3, 4, 5, 6 is reduced and the density of the signal pads 223, 235, 524, 532, 624, 632 is increased.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined by the appended claims.

What is claimed is:

1. A semiconductor package, comprising:
a substrate, having a receiving surface;
a first chip, mechanically and electrically connected to the substrate, and the first chip comprising:
a first major surface;
a first back surface, facing the receiving surface of the substrate;
a plurality of first signal pads, disposed adjacent to the first to major surface;
a plurality of second signal pads, disposed adjacent to the first back surface, wherein the first signal pads are electrically connected to the substrate via the second signal pads;
at least one first power pad, disposed adjacent to the first major surface;
at least one first ground pad, disposed adjacent to the first major surface;
at least one second power pad, disposed adjacent to the first back surface;
at least one second ground pad, disposed adjacent to the first back surface;
at least one first through-chip via, electrically connecting the first power pad and the second power pad; and
at least one fourth through-chip via, electrically connecting the first ground pad and the second ground pad;
an interposer, mechanically and electrically connected to the first chip, and the interposer comprising:
a first surface, facing the first major surface of the first chip;
a second surface;
a plurality of third signal pads, disposed adjacent to the first surface and capacitively coupled to the first signal pads of the first chip, so as to provide proximity communication between the first chip and the interposer;
a redistribution layer, disposed adjacent to the second surface, and having a plurality of fourth signal pads, at least one fourth power pad and at least one fourth ground pad;
at least one first through silicon via, electrically connecting the third signal pads and the fourth signal pads;
at least one third power pad, disposed adjacent to the first surface;
at least one third ground pad, disposed adjacent to the first surface;
at least one second through silicon via, electrically connecting the third power pad and the fourth power pad; and
at least one fifth through silicon via, electrically connecting the third ground pad and the fourth ground pad; and
at least one second conductive element, used for connecting the first chip and the interposer.

2. The semiconductor package as claimed in claim 1, further comprising at least one first passive device disposed adjacent to the interposer.

3. The semiconductor package as claimed in claim 1, further comprising at least one first conductive element for connecting the first chip and the substrate.

4. The semiconductor package as claimed in claim 1, further comprising a second chip disposed on the second surface of the interposer and electrically connected to the interposer via wire-bonding or flip-chip bonding.

5. The semiconductor package as claimed in claim 4, wherein the second chip comprises a second major surface, a plurality of fifth signal pads, at least one fifth power pad and at least one fifth ground pad, the fifth signal pads are disposed adjacent to the second major surface and electrically connected to the fourth signal pads of the interposer, the fifth power pad and the fifth ground pad are disposed adjacent to the second major surface and electrically connected to the fourth power pad and the fourth ground pad of the interposer respectively.

6. A semiconductor package, comprising:
a substrate, having a receiving surface;
a third chip, electrically connected to the substrate, and the third chip comprising:
a third major surface, facing the receiving surface of the substrate;
a third back surface;
a plurality of sixth signal pads, disposed adjacent to the third major surface;
a plurality of seventh signal pads, disposed adjacent to the third back surface;
at least one second through-chip via, electrically connecting the sixth signal pads and the seventh signal pads;
at least one sixth power pad, disposed adjacent to the third major surface;
at least one sixth ground pad, disposed adjacent to the third major surface;
at least one seventh power pad, disposed adjacent to the third back surface;
at least one seventh ground pad, disposed adjacent to the third back surface;
at least one third through-chip via, electrically connecting the sixth power pad and the seventh power pad; and
at least one fifth through-chip via, electrically connecting the sixth ground pad and the seventh ground pad; and
a fourth chip, electrically connected to the third chip, and the fourth chip comprising:
a fourth major surface, facing the third back surface of the third chip;
a plurality of eighth signal pads, disposed adjacent to the fourth major surface and capacitively coupled to the seventh signal pads of the third chip, so as to provide proximity communication between the third chip and the fourth chip;
at least one eighth power pad, disposed adjacent to the fourth major surface and electrically connected to the seventh power pad of the third chip; and
at least one eighth ground pad, disposed adjacent to the fourth major surface and electrically connected to the seventh ground pad of the third chip;
at least one fourth conductive element, used for connecting the third chip and the substrate; and
at least one fifth conductive element, used for connecting the third chip and the fourth chip.

7. The semiconductor package as claimed in claim 6, further comprises at least one second passive device disposed adjacent to the third chip.

8. A semiconductor package, comprising:
a substrate, having a receiving surface;
an interposer, electrically connected to the substrate, and the interposer comprising:
a first surface, facing the receiving surface of the substrate;
a second surface;
a plurality of eighth signal pads, disposed adjacent to the first surface;
a plurality of ninth signal pads, disposed adjacent to the second surface;
at least one third through silicon via, electrically connecting the eighth signal pads and the ninth signal pads;
at least one ninth power pad, disposed adjacent to the first surface;
at least one ninth ground pad, disposed adjacent to the first surface;
at least one tenth power pad, disposed adjacent to the second surface;
at least one tenth ground pad, disposed adjacent to the second surface;
at least one fourth through silicon via, electrically connecting the ninth power pad and the tenth power pad; and
at least one sixth through silicon via, electrically connecting the ninth ground pad and the tenth ground pad; and
a fifth chip, electrically connected to the interposer, and the fifth chip comprising:
a fifth major surface, facing the second surface of the interposer;
a plurality of tenth signal pads, disposed adjacent to the fifth major surface and capacitively coupled to the ninth signal pads of the interposer, so as to provide proximity communication between the interposer and the fifth chip;
at least one eleventh power pad, disposed adjacent to the fifth major surface and electrically connected to the tenth power pad of the interposer; and
at least one eleventh ground pad, disposed adjacent to the fifth major surface and electrically connected to the tenth ground pad of the interposer;
at least one sixth conductive element, used for connecting the interposer and the substrate; and
at least one seventh conductive element, used for connecting the interposer and the fifth chip.

9. The semiconductor package as claimed in claim 8, further comprises at least one third passive device disposed adjacent to the interposer.
